(19) United States
(12) Patent Application Publication
(10) Pub. No.: US 2025/0131158 A1
(43) Pub. Date: Apr. 24, 2025

(54) Method for Validating a Design Model for a Technical System

(71) Applicant: Robert Bosch GmbH, Stuttgart (DE)

(72) Inventor: Maximilian Steeb, Weinstadt (DE)

(21) Appl. No.: 18/914,668

(22) Filed: Oct. 14, 2024

(30) Foreign Application Priority Data
Oct. 19, 2023 (EP) 23204535.1

(51) Int. Cl. G06F 30/20

(52) U.S. Cl. CPC G06F 30/20

(57) ABSTRACT

A method for validating a design model for a technical system includes (i) providing the design model, wherein the design model models the technical system, and wherein the design model indicates an allowable range for at least one parameter of the technical system and for at least one disturbance variable, (ii) initiating an application of a test signal to the technical system, (iii) initiating a capture of an output of the technical system triggered by the test signal, (iv) determining a state of the technical system based on the test signal and the captured output, a respective value for the at least one parameter of the technical system being determined based on the state, (v) determining a disturbance in the technical system based on the test signal, the captured output, and the determined state, wherein a respective value for the at least one disturbance variable is determined, and (vi) validating the design model for the technical system, wherein the respective value for the at least one parameter of the technical system and the respective value for the at least one disturbance variable are compared with the allowable range of the design model. A computer program, a device, and a storage medium for this purpose is also disclosed.

This application claims priority under 35 U.S.C. § 119 to patent application no. EP 23204535.1, filed on Oct. 19, 2023 in Europe, the disclosure of which is incorporated herein by reference in its entirety.

The disclosure relates to a method for validating a design model for a technical system. The disclosure further relates to a computer program, a device, and a storage medium for this purpose.

### BACKGROUND

The model-based controller design for a technical system is based in particular on design models that were used in the development phase to model the technical system to be controlled. Particularly in attempting to provide stability and safety guarantees, uncertainties and disturbance within the design model may be taken into account and may be described as sets of parameters, said parameters in turn being quantitative or stochastic. In the design phase, the technical system is designed, in particular using the design model having the assumed set of parameters, so that stability and safety guarantees can be given taking into account the uncertainties and malfunctions.

For parameter identification of technical systems in general, in particular control systems, there are various algorithms for estimating nominal parameter values, or uncertainty quantification for estimating the parameter distributions of uncertain parameters.

However, in the real application of the technical system, the stability and safety guarantees can only apply for as long as the assumptions regarding the parameters of the design model correspond to the behavior under real conditions.

### SUMMARY

The subject-matter of the disclosure is a method, a computer program, a device, and a computer-readable storage medium having the features set forth below. Further features and details of the disclosure will emerge from the description and the drawings. Features and details which are described in connection with the method according to the disclosure naturally also apply in connection with the computer program according to the disclosure, the device according to the disclosure, and the computer-readable storage medium according to the disclosure, and vice versa in each case, so that reference is always or can always be made to the individual aspects of the disclosure with respect to the disclosure.

The subject matter of the disclosure is in particular a method for validating a design model for a technical system, comprising the following steps, wherein the steps may be repeated and/or performed sequentially. In particular, the technical system comprises at least one control loop. The technical system may also be a feedback control system.

In a first step, preferably the design model is provided, wherein the design model models the technical system. In particular, the design model specifies an allowable range for at least one parameter of the technical system and for at least one disturbance variable. For example, the allowable range may be one minimum and maximum value each or a stochastic distribution for the at least one parameter or the at least one disturbance variable. The at least one parameter may be, for example, a vehicle mass and the at least one disturbance variable, for example, a disturbance force. The allowable range may also be understood as an assumption for the at least one parameter or the at least one disturbance variable, for example based on empirical values or determined by testing.

In a further step, preferably an application of a test signal to the technical system is initiated. For example, the test signal may be a value for a variable in the technical system or in a control loop of the technical system.

In a further step, a detection of an output of the technical system triggered by the test signal is preferably initiated. The output may be, for example, a variable in the technical system or in a control loop of the technical system, or a measurement value of a sensor of the technical system.

In a further step, a state of the technical system is preferably determined based on the test signal and the captured output, wherein a respective value for the at least one parameter of the technical system is determined based on the state. The state may be present as a state vector based on or comprising current values of the at least one parameter, in particular a plurality of parameters.

In a further step, a disturbance is preferably determined in the technical system based on the test signal, the sensed output, and the determined state, wherein a respective value for the at least one disturbance variable is determined. The disturbance may thus be an entirety of the at least one disturbance variable, wherein a plurality of disturbance variables may be present. A disturbance variable may be, for example, an uncontrolled influence, such as a relative travel wind or a friction or a heating.

In a further step, the design model for the technical system is preferably validated, wherein the respective value for the at least one parameter of the technical system and the respective value for the at least one disturbance variable are compared with the allowable range of the design model. Thus, it can be advantageously determined on the one hand whether the design model correctly models the technical system under real conditions and on the other hand whether there is a fault in the technical system.

It can further be advantageously provided that the method further comprises the step of:
transmitting the captured output of the technical system to an external data processing device. For example, the external data processing device may be a server and may be connected wirelessly or wired to the technical system to provide bi-directional communication. Determining the state and determining the disturbance and validating the design model may additionally or alternatively also be performed entirely by the external data processing device. A computational effort can thus advantageously be outsourced at least in part. Further advantageously, a plurality of outputs of individual technical systems may thus be analyzed at a central external data processing device, for example, whereby the design model may be optimized based on the outputs of the plurality of technical systems.

Furthermore, it is contemplated that the technical system is a vehicle. Applying the test signal may be performed accordingly by at least one actuator of the vehicle and capturing the output triggered by the test signal may be performed accordingly by at least one sensor of the vehicle. It is thus possible that the method according to the disclosure is used in a vehicle. The vehicle may, for example, be designed as a motor vehicle and/or a passenger vehicle and/or an autonomous vehicle. The vehicle may comprise a vehicle device, e.g., for providing an autonomous driving function and/or a driver assistance system. The vehicle device may be configured to control and/or accelerate and/or brake and/or steer the vehicle, at least partially automatically.

Preferably, the disclosure may provide that the method further comprises the following step:
performing at least one action based on a result of validating, wherein the at least one action affects the technical system and/or the design model.
   Thus, advantageously in addition to validating, a corresponding reaction may also be provided with respect to both the technical system and the design model based on the result of the validating.

A further advantage may be achieved in the context of the disclosure if performing the at least one action comprises the following step:
adjusting at least one function of the technical system to increase the safety of the technical system by way of the adjustment.
   The adjustment may be, for example, a degrading or deactivating of the function of the technical system. It is contemplated that the degrading or deactivating of the function will occur for a defined period of time. In the case of a vehicle as a technical system, for example, it can be determined in the context of validating that a high level of disturbance is present, i.e. a value for at least one disturbance variable is outside the permissible range of the design model, such that the vehicle cannot be driven due to adjusting the at least one function, for as long as the disturbance, i.e., in particular the value for the at least one disturbance variable, is outside the permissible range of the design model. Furthermore, in the case of a vehicle, adjusting the at least one function may comprise adjusting a planned trajectory of the vehicle. For example, based on the output of the technical system, it may be determined that the design model did not accurately depict the reality, so that the planned trajectory may be advantageously precisely adjusted taking into account the output.

It may be advantageous if, in the context of the disclosure, performing the at least one action comprises the following step:
adjusting the design model based on the result of the validating to customize the design model for the technical system by way of the adjustment.
   The design model may thereby be advantageously iteratively adapted and optimized to a behavior of the technical system under real-world conditions.

For example, it may be provided that the design model is used as a reference for monitoring the technical system and determined based on modeling of the technical system. The design model may describe the technical system at least based on equations and assumptions for the at least one parameter and the at least one disturbance variable. Further, the state may represent at least one physical energy store of the technical system and the disturbance may represent at least one environmental impact on the technical system. For example, the state of a vehicle as a technical system may be a speed of the vehicle and the disturbance may be a relative travel wind.

Another object of the disclosure is a computer program, in particular a computer program product, comprising instructions which, when the computer program is executed by a computer, cause the computer to carry out the method according to the disclosure. The computer program according to the disclosure thus brings with it the same advantages as have been described in detail with reference to a method according to the disclosure.

The disclosure also relates to a device for data processing which is configured to carry out the method according to the disclosure. The device may be a computer, for example, that executes the computer program according to the disclosure. The computer may comprise at least one processor for executing the computer program. A non-volatile data memory may be provided as well, in which the computer program can be stored and from which the computer program can be read by the processor for execution.

The disclosure may also relate to a computer-readable storage medium, which comprises the computer program according to the disclosure and/or instructions that, when executed by a computer, prompt said computer program to carry out the method according to the disclosure. The storage medium is configured as a data memory such as a hard drive and/or a non-volatile memory and/or a memory card, for example. The storage medium may, for example, be integrated into the computer.

In addition, the method according to the disclosure may also be designed as a computer-implemented method.

### BRIEF DESCRIPTION OF THE DRAWINGS

Further advantages, features, and details of the disclosure emerge from the following description, in which exemplary embodiments of the disclosure are described in detail with reference to the drawings. The features mentioned in the claims and in the description may each be essential to the disclosure individually or in any combination. The figures show:

FIG. 1 a schematic visualization of a method, a device, a storage medium, and a computer program according to exemplary embodiments of the disclosure,

FIG. 2 a schematic illustration of a technical system, an actuator, a sensor, and an external data processing device according to exemplary embodiments of the disclosure,

FIG. 3 a schematic illustration of a method according to exemplary embodiments of the disclosure.

### DETAILED DESCRIPTION

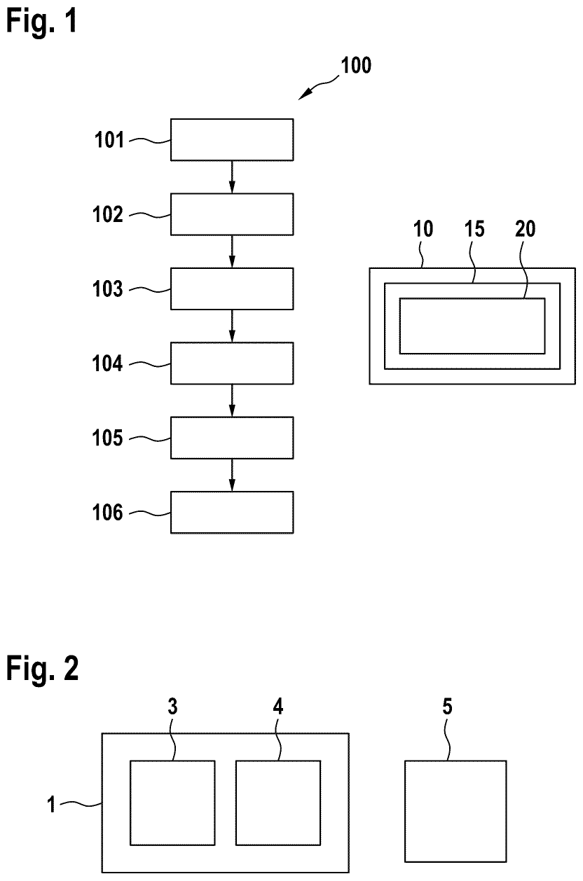

FIG. 1 schematically illustrates a method 100, a device 10, a storage medium 15, and a computer program 20 according to exemplary embodiments of the disclosure.

In particular, FIG. 1 shows an exemplary embodiment of a method 100 for validating a design model 2 for a technical system 1, comprising the following steps. In a first step 101, the design model 2 is provided, the design model 2 modeling the technical system 1. The design model 2 specifies an allowable range for at least one parameter of the technical system 1 and for at least one disturbance variable. In a second step 102, an application of a test signal to the technical system 1 is initiated. In a third step 103, a detection of an output of the technical system 1 triggered by the test signal is initiated. In a fourth step 104, a state of the technical system 1 is determined based on the test signal and the captured output, a respective value for the at least one parameter of the technical system 1 being determined based on the state. In a fifth step 105, a fault is determined in the technical system 1 based on the test signal, the sensed output, and the determined state, a particular value being determined for the at least one disturbance variable. In a sixth step 106, the design model 2 is validated for the technical system 1, wherein the respective value for the at least one parameter of the technical system 1 and the respective value for the at least one disturbance variable are compared to the allowable range of the design model 2.

In FIG. 2, a technical system 1, an actuator 3, a sensor 4, and an external data processing device 5 according to exemplary embodiments of the disclosure are schematically illustrated.

One aspect of the present disclosure according to exemplary embodiments is in particular that a parameter estimation algorithm is used during a run time of the technical system 1 to validate the assumptions made in the development phase of the design model 2 for the individual technical system 1.

If the assumptions, i.e. in particular the allowable ranges, regarding the parameters are violated during the run time, at least one action may be carried out, for example to prevent a failure of the technical system 1. When the parameters are still within the allowable ranges but begin to drift (e.g., due to aging), then the technical system 1 may utilize said information according to a further potential action to optimize the design model 2. The system-specific information about violated assumptions could also advantageously be aggregated for a plurality of technical systems 1 and forwarded to an external data processing device 5 and thus in particular to a development team, to improve the assumptions for the parameters of the design model 2, such that the performance of the technical system 1 can be improved in future updates for the plurality of technical systems 1 by readjusting the design model 2.

In the event of an autonomously driving vehicle as the technical system 1, the design model 2 could be forwarded to a trajectory planner or used to adjust the trajectory of the vehicle. The best matching input trajectories for the individual vehicle may be selected so that the best performance or a high level of safety for the individual vehicle can be ensured. The parameter estimate may already be performed on prototypes of the technical system 1 to detect possible violations of the assumed parameters before the technical system 1 is released. In the event of violations of the assumptions, for example, a release having the current control software could be interrupted. The information of which assumptions for the parameters were incorrect and the quantitative information could then be used directly to adjust the design model 2.

The parameter estimate may be performed on the technical system 1 during the run time. The determined values for the parameters are preferably compared with the assumptions for the parameters, i.e. in particular the allowable ranges, of the design model 2 from the design phase. If the determined values are outside of the allowable ranges of the assumed distributions of the parameters, the technical system 1 can react, for example by the action that at least one function is adjusted, i.e. the technical system 1 transitions to a degradation state, for example, or decouples and prevents switching on again.

The determined parameters may be uploaded to a development cloud according to an exemplary embodiment, where the developers may monitor the parameter distributions in a plurality of technical systems 1 (e.g., a fleet of vehicles) and so improve the assumptions about the distributions of the parameter values, i.e., in particular the design model 2.

The design model 2 for the technical system 1 could also be coordinated individually (e.g., vehicle-specific) on-line during the run time in order to improve the performance with regard to the individual system implementation of the technical system 1. Said performance also varies over the service life of the technical system 1, for example.

The method of parameter validation, in particular validation of the design model 2, according to an exemplary embodiment may generally be used for all types of technical systems 1 in which a model-based controller design method has been employed.

In order to illustrate the method according to a possible exemplary embodiment, said embodiment is described below for a lateral control of highly automated vehicles (e.g. SAE level 4). The design model 2 for the lateral control is preferably derived from a linearized single-track model. For example, the state vector is defined as:

x=[ψₑ,\dot{ψ}ₑ,β,yₑ,int(yₑ),δ,\dot{δ}]^{T}
wherein, in particular, the state is ψₑ a vehicle yaw angle deviation, the state is \dot{ψ}ₑ a vehicle yaw rate error, the state β is the float angle, the state is yₑ a lateral error, the state is int(yₑ) an integrated lateral side error, and the state is δ a wheel steering angle.

For the resulting technical system 1 in the form of a closed control system, the state space representation can be represented in the following form:

\dot{x}=A [symbol] x+B_{c}u+E_{c}w

y=Cx

with the test signals in the form of the inputs u=[\dot{ψ}_{d}, \ddot{ψ}_{d}]^{T}, wherein \dot{ψ}_{d} a desired yaw rate and \ddot{ψ}_{d} a desired yaw acceleration and the additive disturbance w=[Δδ, F_{dist}, M_{dist}]^{T}, the disturbance variable being Δδ a wheel steering angle error, the disturbance variable being F_{dist} lateral disturbance force, and the disturbance variable being M_{dist} a disturbance moment about the vertical axis of the vehicle.

In particular, the system matrices comprise a series of parameters that may be θ=[c_{f}, cᵣ, l_{f}, lᵣ, m, J_{z}, vᵥₑₕ, . . . ]^{T} represented as a parameter vector. In the real technical system 1, in particular the vehicle, for example, said parameters are not constant but can vary within certain limits, i.e. the technical system 1 can have parametric uncertainties. In addition, it may be assumed that the inputs \dot{ψ}_{d}, \ddot{ψ}_{d} and disturbance variables acting Δδ, F_{dist}, M_{dist} on the technical system 1 are also within certain limits. During the design phase, the limits, i.e. in particular the allowable ranges, for the parameters and disturbance variables may be approximated, for example by system identification and/or by expert estimates.

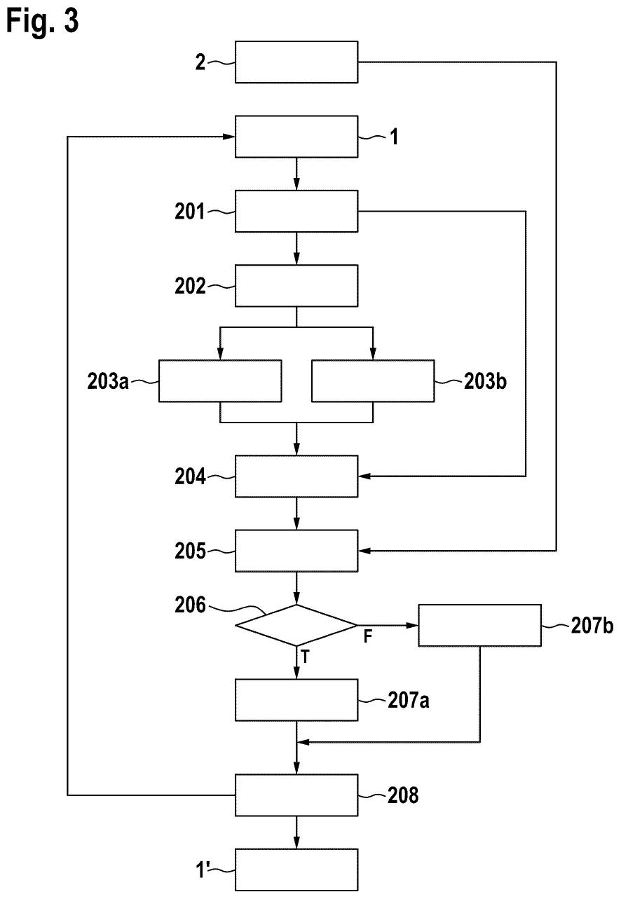

FIG. 3 shows a schematic representation of a method according to an exemplary embodiment showing the flow of information within a technical system 1, in particular a vehicle. The following steps are preferably applied cyclically. In a first step 201, a test signal in the form of a control input is given to the technical system 1 in the form of a feedback control system. In a second step 202, a response of the technical system 1 is measured by way of at least one sensor 4, e.g., an Ineratial Measurement Unit or other vehicle sensors. In a third step, a state of the technical system 1 on the one hand 203a and a disturbance on the other w 203b are estimated. In a fourth step 204, a parameter identification algorithm for estimating the parameter vector @ is performed. In a fifth step 205, a single comparison is made between the identified parameters and the allowable ranges assumed for the design model 2. In a sixth step 206, it is checked whether the individual comparison from step 205 resulted in violated assumptions of the allowable ranges of the design model 2. If yes (path “T” for true in FIG. 3), at least one action may be taken and the determined values of the parameters may be transferred to a development cloud, for example (Step 207a). If no (path “F” for false in FIG. 3), an adjustment of the design model 2 may be performed. Further, in the case of a vehicle as the technical system 1, updated parameters may be used for trajectory planning to provide vehicle-specific optimal trajectories for better performance and safety (Step 207b). Also in the present alternative, the determined parameters may be further transferred to the development cloud. Thus, as a result, individual actions and feedback for the design model 2 (step 208) are obtained, as well as a technical system 1′ optimized in terms of safety and/or performance.

The above explanation of the embodiments describes the present disclosure solely within the scope of examples. Of course, individual features of the embodiments can be freely combined with one another, if technically feasible, without leaving the scope of the present disclosure.

What is claimed is:

1. A method for validating a design model for a technical system, comprising:
providing the design model, wherein the design model models the technical system, and wherein the design model indicates an allowable range for at least one parameter of the technical system and for at least one disturbance variable;
initiating an application of a test signal to the technical system;
initiating a capture of an output of the technical system triggered by the test signal;
determining a state of the technical system based on the test signal and the captured output, a respective value for the at least one parameter of the technical system being determined based on the state;
determining a disturbance in the technical system based on the test signal, the captured output, and the determined state, wherein a respective value for the at least one disturbance variable is determined; and
validating the design model for the technical system, wherein the respective value for the at least one parameter of the technical system and the respective value for the at least one disturbance variable are compared with the allowable range of the design model.

2. The method according to claim 1, further comprising transmitting the captured output of the technical system to an external data processing device,
wherein determining the state and determining the disturbance and validating the design model are additionally performed by the external data processing device.

3. The method according to claim 1, wherein:
the technical system is a vehicle,
the applying of the test signal is performed by at least one actuator of the vehicle, and
the capturing of the output triggered by the test signal is performed by at least one sensor of the vehicle.

4. The method according to claim 1, further comprising performing at least one action based on a result of validating,
wherein the at least one action affects the technical system and/or the design model.

5. The method according to claim 4, wherein the performing of the at least one action comprises adjusting at least one function of the technical system to increase the safety of the technical system by way of the adjustment.

6. The method according to claim 4, wherein the performing of the at least one action comprises adjusting the design model based on the result of validating to customize the design model for the technical system by way of the adjustment.

7. The method according to claim 1, wherein:
the design model is used as a reference for monitoring the technical system and is determined based on modeling of the technical system, and
the state represents at least one physical energy store of the technical system and the disturbance represents at least one environmental impact on the technical system.

8. A computer program comprising instructions for causing the computer to carry out the method according to claim 1 when the computer program is executed by a computer.

9. A device for data processing configured to carry out the method according to claim 1.

10. A computer-readable storage medium, comprising instructions which, when executed by a computer, cause said computer to carry out the steps of the method according to claim 1.
